(19) United States
(12) Patent Application Publication
(10) Pub. No.: US 2013/0069189 A1
(43) Pub. Date: Mar. 21, 2013

(54) BONDING PAD STRUCTURE AND FABRICATING METHOD THEREOF

(71) Applicant: Ching-Hung Kao, Zhudong Township (TW)

(72) Inventor: Ching-Hung Kao, Zhudong Township (TW)

(73) Assignee: UNITED MICROELECTRONICS CORPORATION, Hsinchu (TW)

(21) Appl. No.: 13/236,780

(22) Filed: Sep. 20, 2011

(51) Int. Cl. H01L 31/0232

(52) U.S. Cl. 257/432; 438/70; 257/E31.127

(57) ABSTRACT

A bonding pad structure is used in an integrated circuit device. The integrated circuit device includes a semiconductor substrate with a first surface and a second surface. The bonding pad structure includes a dielectric layer, a conductor structure, a pad opening and an isolation trench. The dielectric layer is formed on the second surface of the semiconductor substrate. The conductor structure is disposed within the dielectric layer. The pad opening is formed in the first surface of the semiconductor substrate. The pad opening runs through the semiconductor substrate and a part of the dielectric layer, so that the conductor structure is exposed. The isolation trench has an opening in the first surface of the semiconductor substrate. The isolation trench runs through the semiconductor substrate and a part of the dielectric layer, and the isolation trench is disposed around the pad opening.

### FIELD OF THE INVENTION

The present invention relates to a bonding pad structure, and more particularly to a bonding pad structure for use in an integrated circuit device. The present invention also relates to a method of fabricating such a bonding pad structure.

### BACKGROUND OF THE INVENTION

Due to small size and low cost, a complementary metal oxide semiconductor image sensor (also referred as CIS) is widely used in various image pickup devices. FIG. 1A is a schematic cross-sectional view illustrating a conventional complementary metal oxide semiconductor image sensor fabricated by a front side illumination technology. After an incident light is transmitted through a microlens layer 11 and a color filter layer 12, the incident light is directed to a photodiode 15 in a substrate 1 through a metal wiring layer 13 and a dielectric layer 14. Since metal wiring layer 13 and the dielectric layer 14 are very thick, the light sensitivity is usually insufficient.

For solving the above drawbacks, a complementary metal oxide semiconductor image sensor fabricated by a back side illumination (BSI) technology has been disclosed. FIG. 1B is a schematic cross-sectional view illustrating a conventional complementary metal oxide semiconductor image sensor fabricated by a back side illumination technology. After a backside of a substrate 1 is thinned, a color filter layer 12 and a microlens layer 11 are formed on the backside of the substrate. Since the incident light is directed to a photodiode 15 from the backside of the substrate 1, the optical path of the incident light is shortened and the light sensitivity is enhanced.

However, for producing a bonding pad opening from the backside of the substrate 1, the substrate 1 should be drilled to form a contact hole. Consequently, the metal structure serving as the bonding pad will be exposed. Since the substrate is made of silicon, the wire is possibly contacted with the silicon-made sidewall of the contact hole during the subsequent wire-bonding process. Under this circumstance, a short-circuited problem occurs. For avoiding the short-circuited problem, an insulating layer is formed on the sidewall of the contact hole by an additional processing step. The additional processing step of forming the insulating layer may increase the fabricating cost. Therefore, there is a need of providing an improved bonding pad structure so as to obviate the drawbacks encountered from the prior art.

### SUMMARY OF THE INVENTION

In accordance with an aspect, the present invention provides a bonding pad structure for use in an integrated circuit device. The integrated circuit device includes a semiconductor substrate with a first surface and a second surface. The bonding pad structure includes a dielectric layer, a conductor structure, a pad opening and an isolation trench. The dielectric layer is formed on the second surface of the semiconductor substrate. The conductor structure is disposed within the dielectric layer. The pad opening is formed in the first surface of the semiconductor substrate. The pad hole runs through the semiconductor substrate and a part of the dielectric layer, so that the conductor structure is exposed. The isolation trench has an opening in the first surface of the semiconductor substrate. The isolation trench runs through the semiconductor substrate and a part of the dielectric layer, and the isolation trench is disposed around the pad opening.

In an embodiment, the bonding pad structure further includes an etch stop structure, which is disposed within the dielectric layer and located at a bottom of the isolation trench.

In an embodiment, the conductor structure and the etch stop structure are in contact with each other, and the conductor structure and the etch stop structure are both made of metallic material.

In an embodiment, the conductor structure and the etch stop structure are separated from each other.

In an embodiment, the etch stop structure is disposed around the etch stop structure, and the conductor structure and the etch stop structure are both made of metallic material.

In an embodiment, a photodiode is disposed with the semiconductor substrate, and a color filter layer and a microlens layer are formed on the first surface of the semiconductor substrate.

In an embodiment, a protecting layer is formed on the first surface of the semiconductor substrate and the microlens layer.

In an embodiment, a multi-layered wiring structure including at least one metal wiring layer and at least one dielectric layer is further disposed on the dielectric layer.

In an embodiment, the multi-layered wiring structure is further bonded to a handle wafer.

In accordance with another aspect, the present invention provides a method of fabricating a bonding pad structure in the production of an integrated circuit. Firstly, a semiconductor substrate is provided, wherein the semiconductor substrate has a first surface and a second surface. Then, a dielectric layer is formed on the second surface of the semiconductor substrate, wherein a conductor structure is disposed within the dielectric layer. Afterwards, a pad opening and an isolation trench are formed, wherein the pad opening runs through the semiconductor substrate and a part of the dielectric layer, so that the conductor structure is exposed, wherein the isolation trench runs through the semiconductor substrate and a part of the dielectric layer, and the isolation trench is disposed around the pad opening.

In an embodiment, the bonding pad structure further includes an etch stop structure for stopping formation of the isolation trench during a process of etching the isolation trench.

In an embodiment, the conductor structure and the etch stop structure are in contact with each other, and the conductor structure and the etch stop structure are both made of metallic material.

In an embodiment, the conductor structure and the etch stop structure are separated from each other.

In an embodiment, the etch stop structure is disposed around the etch stop structure, and the conductor structure and the etch stop structure are both made of metallic material.

In an embodiment, the method further includes steps of forming a photodiode in the semiconductor substrate, and forming a color filter layer and a microlens layer on the first surface of the semiconductor substrate.

In an embodiment, the method further includes a step of forming a protecting layer on the first surface of the semiconductor substrate and the microlens layer.

In an embodiment, the method further includes a step of forming a multi-layered wiring structure on the dielectric layer, wherein the multi-layered wiring structure includes at least one metal wiring layer and at least one dielectric layer.

In an embodiment, the method further includes a step of bonding the multi-layered wiring structure to a handle wafer.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic cross-sectional view illustrating a conventional complementary metal oxide semiconductor image sensor fabricated by a front side illumination technology;

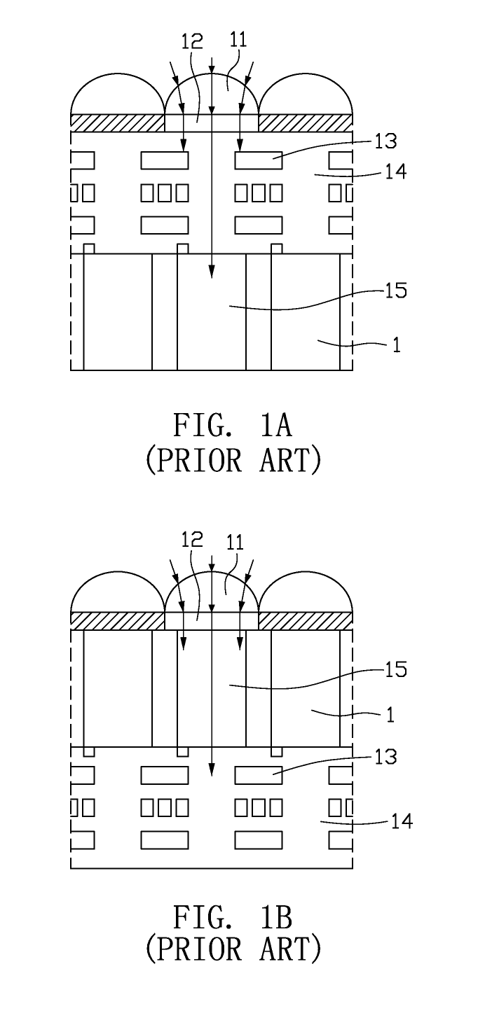

FIG. 1B is a schematic cross-sectional view illustrating a conventional complementary metal oxide semiconductor image sensor fabricated by a back side illumination technology;

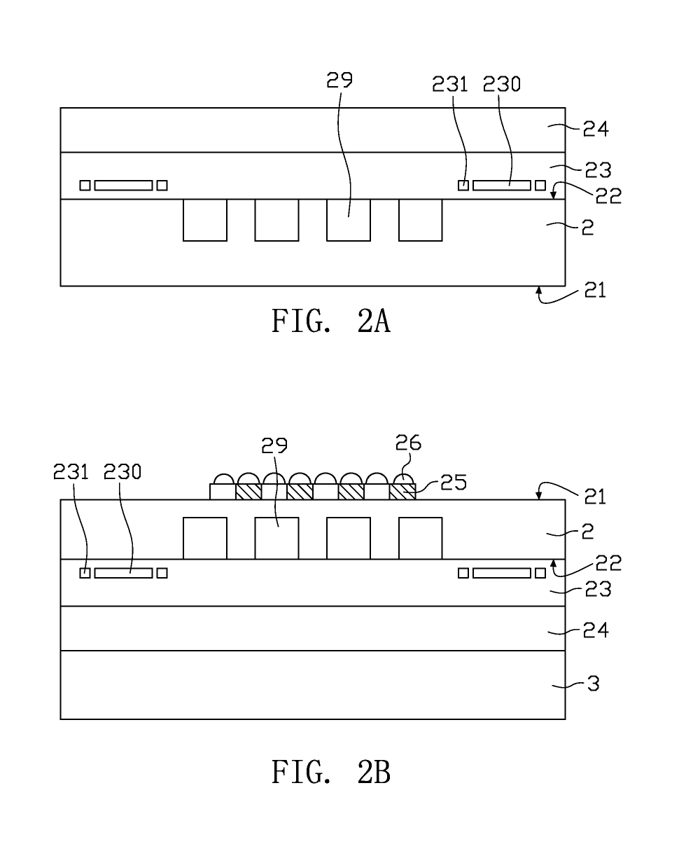

FIGS. 2A˜2E are schematic cross-sectional views illustrating a method for fabricating a bonding pad structure according to an embodiment of the present invention;

FIG. 3A is a schematic top view illustrating the conductor structure and the etch stop structure of the bonding pad structure of the present invention; and

FIG. 3B is a schematic top view illustrating the pad opening and the isolation trench of the bonding pad structure of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

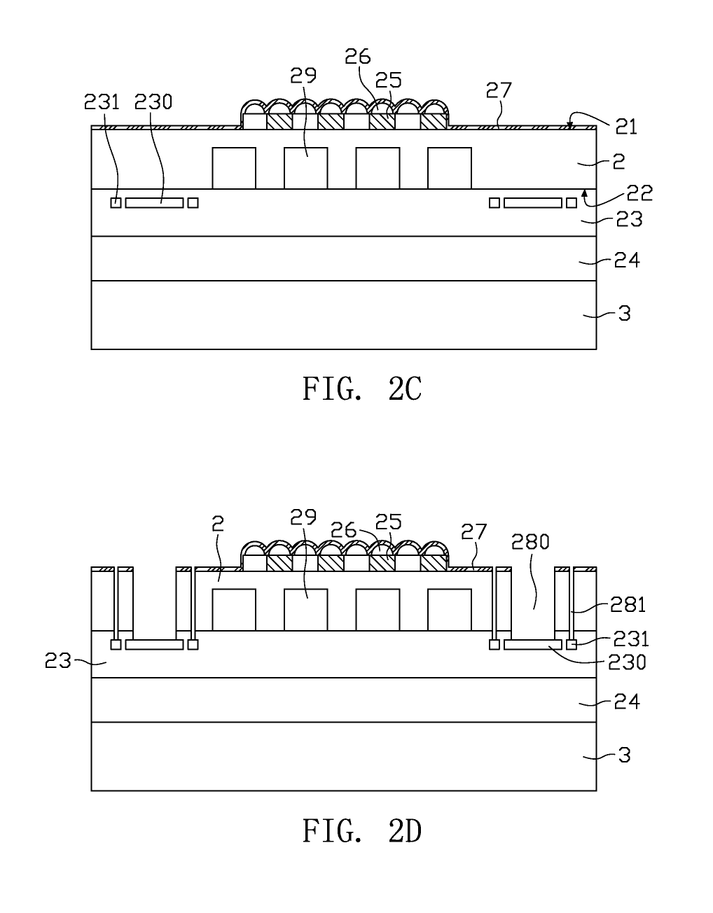

FIGS. 2A˜2E are schematic cross-sectional views illustrating a method for fabricating a bonding pad structure according to an embodiment of the present invention. The method can be applied to the production of various integrated circuit chips, especially a complementary metal oxide semiconductor image sensor.

First of all, as shown in FIG. 2A, a semiconductor substrate 2 is provided. The semiconductor substrate 2 has a first surface 21 and a second surface 22. A multi-layered wiring structure 24 including a metal wiring layer and a dielectric layer is located at the side of the second surface 22 of the semiconductor substrate 2. In addition, a flat dielectric layer 23 is disposed adjacent to the second surface 22 of the semiconductor substrate 2. A conductor structure 230 and an etch stop structure 231 are formed within the dielectric layer 23. The conductor structure 230 can be used as the bonding pad of the complementary metal oxide semiconductor image sensor. Moreover, as shown in FIG. 2A, a photodiode 29 is formed in the semiconductor substrate 2.

Then, as shown in FIG. 2B, the multi-layered wiring structure 24 at the side of the second surface 22 of the semiconductor substrate 2 is bonded to a handle wafer 3. After the first surface 21 of the semiconductor substrate 2 is thinned, a color filter layer 25 and a microlens layer 26 are sequentially formed on the first surface 21 of the semiconductor substrate 2.

Then, as shown in FIG. 2C, a protecting layer 27 is formed on the first surface 21 of the semiconductor substrate 2 and the surface of the microlens layer 26.

Then, a photolithography and etching process is performed to form a pad opening 280 and an isolation trench 281 (see FIG. 2D). The pad opening 280 runs through the semiconductor substrate 2 and a part of the dielectric layer 23, so that the conductor structure 230 is exposed. The isolation trench 281 runs through the semiconductor substrate 2 and a part of the dielectric layer 23 to the etch stop structure 231. Then, the handle wafer 3 is removed, and a wiring structure 282 is produced (see FIG. 2E). In such way, the isolation trench 281 is disposed around the pad opening 280 to achieve good insulating efficacy. In the subsequent process of wiring to the conductor structure 230 through the pad opening 280 or using other electrically connection manners, the good insulating efficacy can effectively avoid the short-circuited problem.

In this embodiment, the semiconductor substrate 2 is a silicon substrate, and the protecting layer 27 is made of silicon oxide or silicon oxynitride (SiON), and the dielectric layer 23 is made of silicon oxide or low-K material.

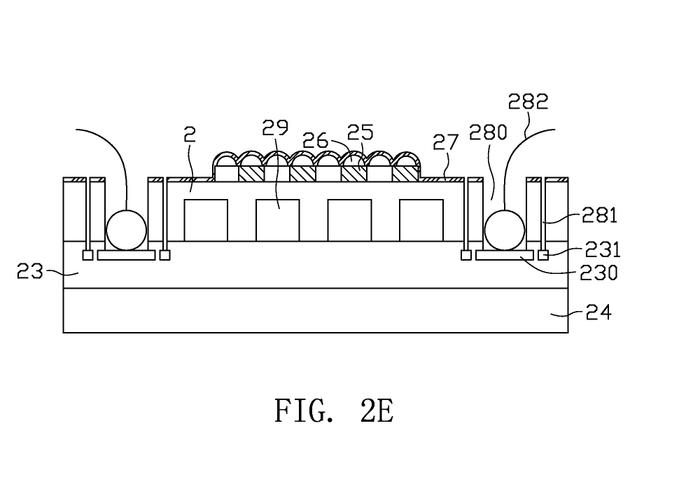

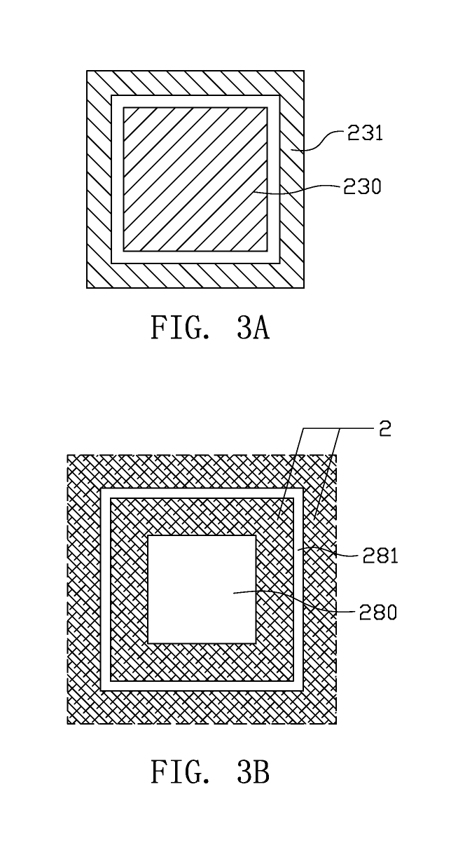

FIG. 3A is a schematic top view illustrating the conductor structure 230 and the etch stop structure 231. The conductor structure 230 is used as the bonding pad. The etch stop structure 231 is disposed around the conductor structure 230. During a process of etching the isolation trench 281, the etch stop structure 231 is configured for stopping formation of the isolation trench 281. For simplifying the fabricating process, the conductor structure 230 and the etch stop structure 231 are both made of metallic material, and produced by defining the same metal layer. In this embodiment, the conductor structure 230 and the etch stop structure 231 are separated from each other by a distance of about 0.5˜20 μm, and the width of the etch stop structure 231 is about 0.1˜20 μm. In some embodiments, the conductor structure 230 and the etch stop structure 231 are in contact with each other, and the conductor structure 230 and the etch stop structure 231 are both made of metallic material. Alternatively, the conductor structure 230 and the etch stop structure 231 may be made of different materials. The etch stop structure 231 is configured for providing a proper etching depth. The depth of the etch stop structure 231 is not necessarily identical to the depth of the conductor structure 230 as long as the depth of the etch stop structure 231 reaches the dielectric layer 23.

FIG. 3B is a schematic top view illustrating the pad opening 280 and the isolation trench 281. As shown in FIG. 3B, the isolation trench 281 is disposed around the pad opening 280 to achieve good insulating efficacy. During the subsequent process of wiring to the conductor structure 230 through the pad opening 280, the good insulating efficacy can effectively avoid the short-circuited problem. In the above embodiment, the isolation trench 281 is a single-loop trench. For minimizing the short-circuited problem, the isolation trench disposed around the pad opening 280 may include multiple loops.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A bonding pad structure for use in an integrated circuit device, the integrated circuit device comprising a semiconductor substrate with a first surface and a second surface, the bonding pad structure comprising:
a dielectric layer formed on the second surface of the semiconductor substrate;
a conductor structure disposed within the dielectric layer;
a pad opening formed in the first surface of the semiconductor substrate, wherein the pad opening runs through the semiconductor substrate and a part of the dielectric layer, so that the conductor structure is exposed; and
an isolation trench having an opening in the first surface of the semiconductor substrate, wherein the isolation trench runs through the semiconductor substrate and a part of the dielectric layer, and the isolation trench is disposed around the pad opening.

2. The bonding pad structure according to claim 1, wherein the bonding pad structure further comprises an etch stop structure, which is disposed within the dielectric layer and located at a bottom of the isolation trench.

3. The bonding pad structure according to claim 2, wherein the conductor structure and the etch stop structure are in contact with each other, and the conductor structure and the etch stop structure are both made of metallic material.

4. The bonding pad structure according to claim 2, wherein the conductor structure and the etch stop structure are separated from each other.

5. The bonding pad structure according to claim 4, wherein the etch stop structure is disposed around the etch stop structure, and the conductor structure and the etch stop structure are both made of metallic material.

6. The bonding pad structure according to claim 1, wherein a photodiode is disposed with the semiconductor substrate, and a color filter layer and a microlens layer are formed on the first surface of the semiconductor substrate.

7. The bonding pad structure according to claim 6, wherein a protecting layer is formed on the first surface of the semiconductor substrate and the microlens layer.

8. The bonding pad structure according to claim 1, wherein a multi-layered wiring structure including at least one metal wiring layer and at least one dielectric layer is further disposed on the dielectric layer.

9. The bonding pad structure according to claim 8, wherein the multi-layered wiring structure is further bonded to a handle wafer.

10. A method of fabricating a bonding pad structure in the production of an integrated circuit, the method comprising steps of:
providing a semiconductor substrate, wherein the semiconductor substrate has a first surface and a second surface;
forming a dielectric layer on the second surface of the semiconductor substrate, wherein a conductor structure is disposed within the dielectric layer; and
forming a pad opening and an isolation trench, wherein the pad opening runs through the semiconductor substrate and a part of the dielectric layer, so that the conductor structure is exposed, wherein the isolation trench runs through the semiconductor substrate and a part of the dielectric layer, and the isolation trench is disposed around the pad opening.

11. The method according to claim 10, wherein the bonding pad structure further comprises an etch stop structure for stopping formation of the isolation trench during a process of etching the isolation trench.

12. The method according to claim 11, wherein the conductor structure and the etch stop structure are in contact with each other, and the conductor structure and the etch stop structure are both made of metallic material.

13. The method according to claim 11, wherein the conductor structure and the etch stop structure are separated from each other.

14. The method according to claim 13, wherein the etch stop structure is disposed around the etch stop structure, and the conductor structure and the etch stop structure are both made of metallic material.

15. The method according to claim 10, further comprising steps:
forming a photodiode in the semiconductor substrate; and
forming a color filter layer and a microlens layer on the first surface of the semiconductor substrate.

16. The method according to claim 15, further comprising a step of forming a protecting layer on the first surface of the semiconductor substrate and the microlens layer.

17. The method according to claim 10, further comprising a step of forming a multi-layered wiring structure on the dielectric layer, wherein the multi-layered wiring structure includes at least one metal wiring layer and at least one dielectric layer.

18. The method according to claim 17, further comprising a step of bonding the multi-layered wiring structure to a handle wafer.
